(19) United States
(12) Patent Application Publication
(10) Pub. No.: US 2026/0358867 A1
(43) Pub. Date: Nov. 12, 2026

(54) THERMAL APPARATUS FOR AN INFORMATION HANDLING SYSTEM

(71) Applicant: Dell Products L.P., Round Rock, TX (US)

(72) Inventors: Enoch Chen, Taipei City (TW); Travis C. North, Cedar Park, TX (US); Pomin Shih, Taipei City (TW)

(21) Appl. No.: 19/199,821

(22) Filed: May 6, 2025

(51) Int. Cl. G06F 1/20; H05K 7/20

(52) U.S. Cl. CPC G06F 1/20; H05K 7/20154; H05K 7/20336; H05K 7/2039

(57) ABSTRACT

Thermal apparatus for an information handling system, comprising a heat transfer device, including: a top cover; a bottom cover opposite to the top cover, the bottom cover including a first surface and a second surface opposite to the first surface; and a wicked structure layer positioned on the first surface of the bottom cover; a heatsink formed on the heat transfer device; and a fan coupled to the heat transfer device and the fin stack, wherein the bottom cover and the heatsink are a single continuous member.

### BACKGROUND

### Field of the Disclosure

The disclosure relates generally to a thermal apparatus for an information handling system.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Heat transfer devices in information handling systems, such as heat sinks and cooling fans, are essential for maintaining optimal performance and preventing overheating. Heat sinks absorb and dissipate heat from critical components like the CPU and GPU. Cooling fans enhance airflow, helping to remove heat from the system more efficiently.

### SUMMARY

Innovative aspects of the subject matter described in this specification may be embodied in a thermal apparatus for an information handling system, including a heat transfer device, including: a top cover; a bottom cover opposite to the top cover, the bottom cover including a first surface and a second surface opposite to the first surface; and a wicked structure layer positioned on the first surface of the bottom cover; a heatsink formed on the heat transfer device; and a fan coupled to the heat transfer device and the fin stack, wherein the bottom cover and the heatsink are a single continuous member.

Other embodiments of these aspects include corresponding systems, apparatus, and methods.

These and other embodiments may each optionally include one or more of the following features. For instance, the single continuous member further includes the wicked structure layer. The bottom cover, the heatsink, and the wicked structure layer are formed from the same material. The heatsink is formed on the second surface of the bottom cover. The heatsink is a parallel finstack. The heatsink is a honeycomb heatsink. The single continuous member is coupled to the top cover. The heat transfer device is a vapor chamber. The heat transfer device is a heat pipe.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a block diagram of an information handling system.

FIG. 3 illustrates a perspective view of a thermal apparatus.

FIG. 4 illustrates a top down view of the thermal apparatus.

FIG. 5 illustrates an exploded view of a heat transfer device of the thermal apparatus.

FIG. 6 illustrates a side view of a heatsink of the thermal apparatus, in a first embodiment.

FIG. 7 illustrates a side view of the heatsink of the thermal apparatus, in a second embodiment.

FIG. 8 illustrates a perspective view of the heat transfer device.

FIG. 9 illustrates a method of forming the thermal apparatus.

### DESCRIPTION OF PARTICULAR EMBODIMENT(S)

This disclosure discusses a thermal apparatus for an information handling system. In short, the invention involves integrating a heatsink with a heat transfer device using electrochemical additive manufacturing. This process allows the heatsink to be formed as one continuous unit with the heat transfer device's bottom layer. Subsequently, the bottom cover is brazed to the top cover. This manufacturing advancement enables a variety of heatsink designs, enhancing thermal management efficiency by optimizing the heat dissipation surface area and airflow. Further, integrating the heatsink with the heat transfer device to make one continuous body eliminates thermal resistance from soldering the heat transfer device to the heatsink. Additionally, a honeycomb structure design can be implemented as the heat transfer device to optimize cooling efficiency.

Specifically, this disclosure discusses a thermal apparatus for an information handling system, comprising a heat transfer device, including: a top cover; a bottom cover opposite to the top cover, the bottom cover including a first surface and a second surface opposite to the first surface; and a wicked structure layer positioned on the first surface of the bottom cover; a heatsink formed on the heat transfer device; and a fan coupled to the heat transfer device and the fin stack, wherein the bottom cover and the heatsink are a single continuous member.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

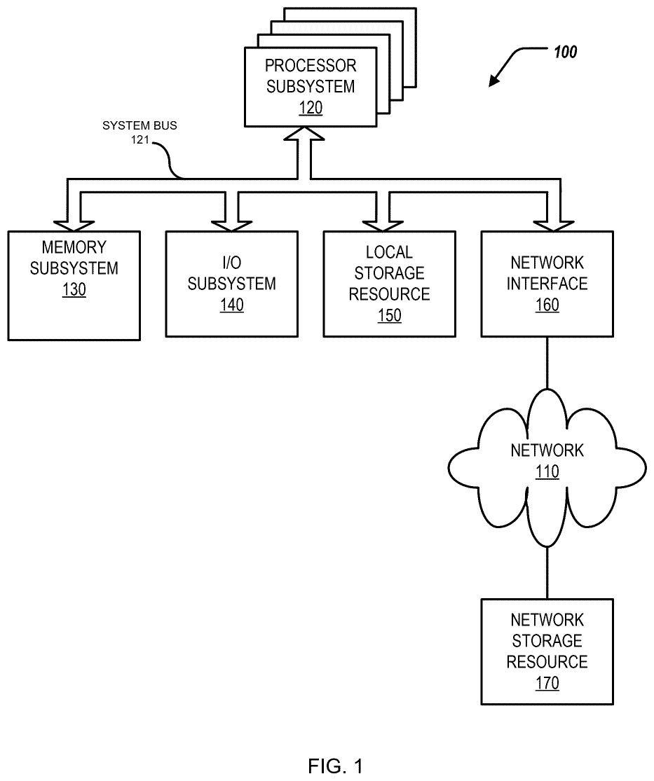

Particular embodiments are best understood by reference to FIGS. 1-9 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

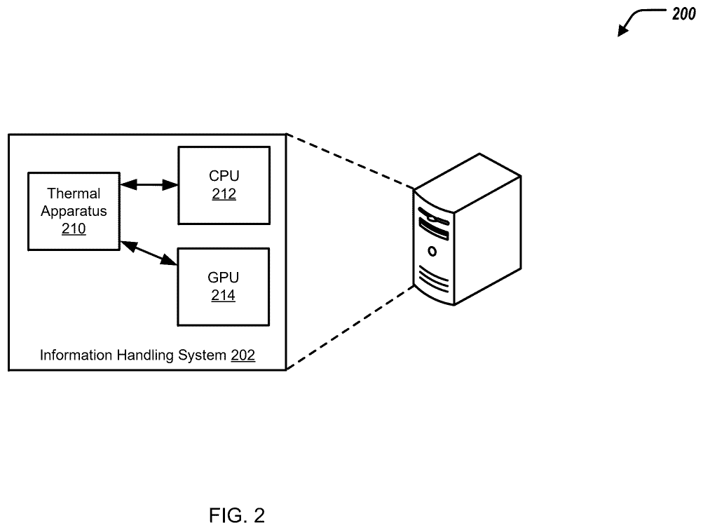

Turning to FIG. 2, FIG. 2 illustrates an environment 200 including an information handling system 202. The information handling system 202 can include a thermal apparatus 210, a CPU 212, and a GPU 214. In some examples, the information handling system 202 is similar to, or includes, the information handling system 100 of FIG. 1. In some examples, the CPU 212 and/or the GPU 214 is the same, or substantially the same, as the processor subsystem 120 of FIG. 1.

The thermal apparatus 210 can be in thermal communication with the CPU 212 and the GPU 214.

In short, the invention involves integrating a heatsink with a heat transfer device using electrochemical additive manufacturing. This process allows the heatsink to be formed as one continuous unit with the heat transfer device's bottom layer. Subsequently, the bottom cover is brazed to the top cover. This manufacturing advancement enables a variety of heatsink designs, enhancing thermal management efficiency by optimizing the heat dissipation surface area and airflow. Further, integrating the heatsink with the heat transfer device to make one continuous body eliminates thermal resistance from soldering the heat transfer device to the heatsink. Additionally, a honeycomb structure design can be implemented as the heat transfer device to optimize cooling efficiency.

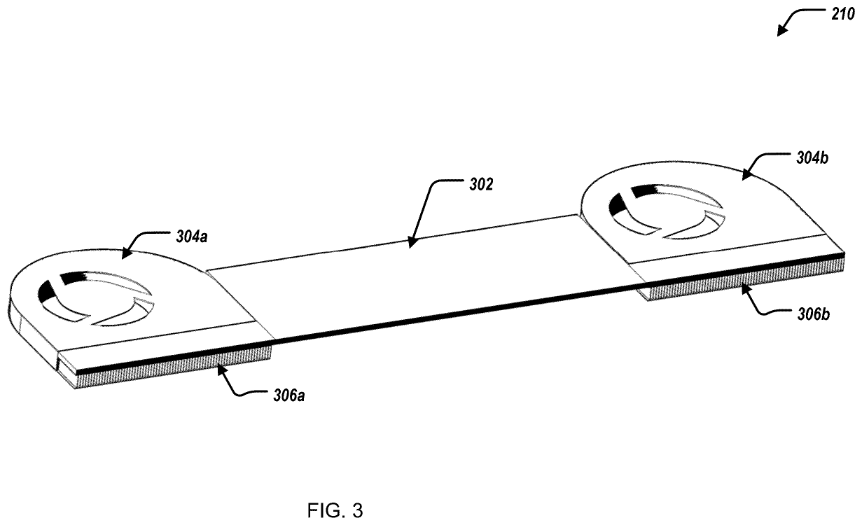

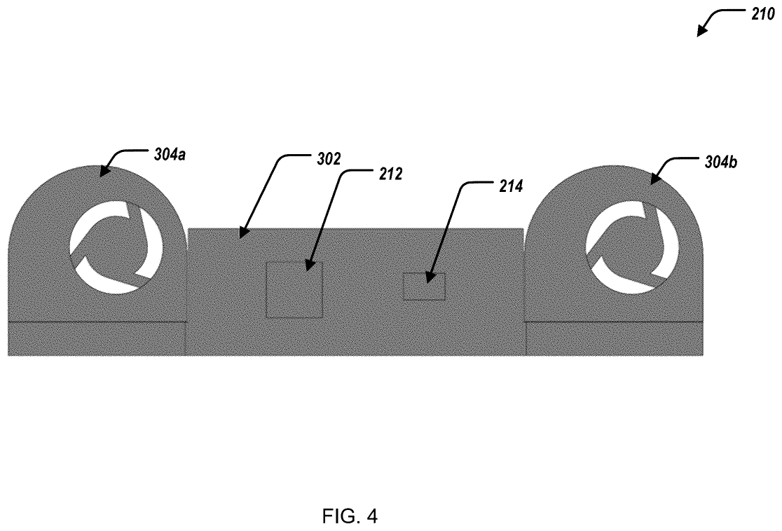

FIG. 3 illustrates a perspective view of the thermal apparatus 210; and FIG. 4 illustrates a top down view of the thermal apparatus 210. Referring to FIGS. 3 and 4, the thermal apparatus 210 includes a heat transfer device 302, fans 304a and 304b (collectively referred to as fans 304), and heatsinks 306a and 306b (collectively referred as heatsinks 306).

In some examples, the heat transfer device 302 is a vapor chamber. In some examples, the heat transfer device 302 is a heat pipe.

In some examples, the fans 304 are coupled to the heat transfer device 302. In some examples, the fans 304 are coupled to respective heatsinks 306.

The heat transfer device 302 is in thermal communication with the CPU 212 and the GPU 214; with the fans 304; and with the heatsinks 306. The fans 304 are in thermal communication with the heatsinks 306. To that end, the thermal apparatus 210 can facilitate dissipation of thermal energy (heat) generated by the CPU 212 and the GPU 214. Specifically, the heat transfer device 302 can transfer thermal energy from the CPU 212 and the GPU 214 to the heatsinks 306, with the fans 304 dissipating such thermal energy out of the information handling system 202.

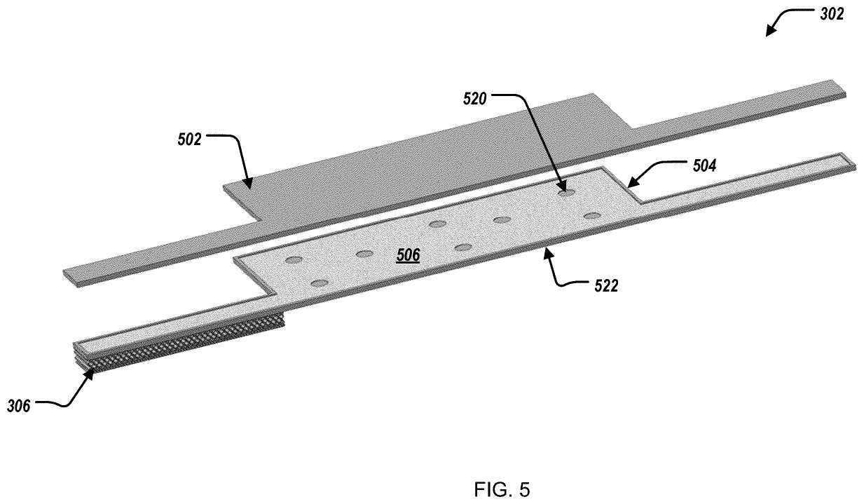

FIG. 5 illustrates an exploded view of the heat transfer device 302. The heat transfer device 302 can include a top cover 502, a bottom cover 504, a wicked structure layer 506, and the heatsink 306. The bottom cover 504 is opposite to the top cover 502. The bottom cover 504 includes a first surface 520 and a second surface 522 opposite to the first surface 520. The wicked structure layer 506 is positioned between the top cover 502 and the bottom cover 504, and in particular, positioned on the first surface 520 of the bottom cover 504. The heatsink 306 is formed on the heat transfer device 302; and in particular is formed on the second surface 522 of the bottom cover 504 of the heat transfer device 302. For simplicity of illustration, only a single heatsink 306 is shown; however, any number of heatsinks can be formed on the heat transfer device 302.

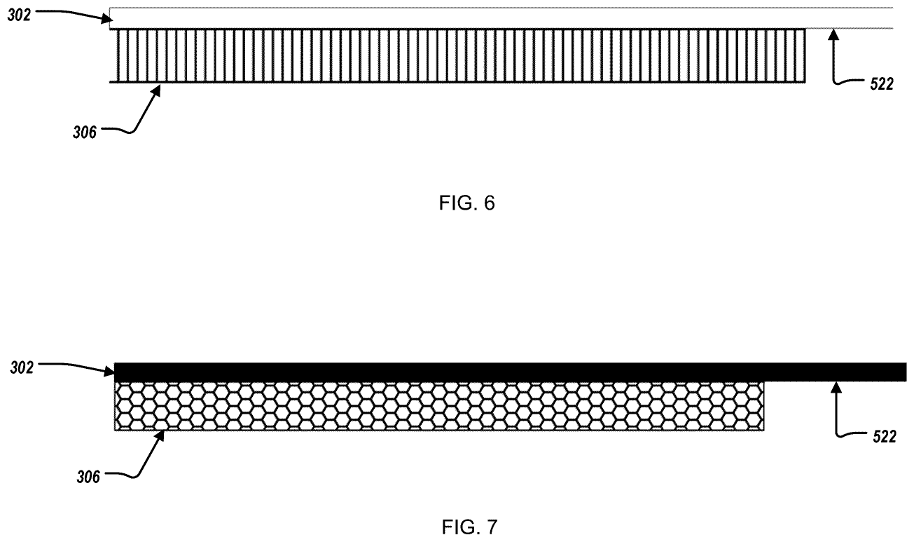

In some examples, the heatsink 306 is a parallel finstack, as shown in FIG. 6. In some examples, the heatsink 306 is a honeycomb heatsink, as shown in FIG. 7.

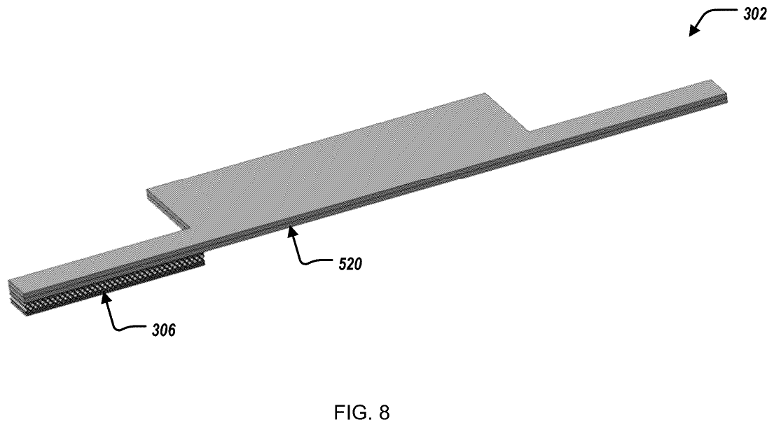

FIG. 8 is a perspective view of the heat transfer device 302. Referring to FIGS. 5 and 8, to that end, the bottom cover 504 of the heat transfer device 302 and the heatsink 306 are a single continuous member (or body). In other words, the bottom cover 504 of the heat transfer device 302 and the heatsink 306 are a single continuous member that is uninterrupted in space; the bottom cover 504 of the heat transfer device 302 and the heatsink 306 are a single continuous member that is unbroken. Specifically, the heatsink 306 is integrated with the heat transfer device 302 to form the single continuous member. In other words, the heat transfer device 302 and the heatsink 306 are a single continuous member that is uninterrupted in space; the heat transfer device 302 and the heatsink 306 are a single continuous member that is unbroken. The heatsink 306 can be integrated with the heat transfer device 302 through electrochemical additive manufacturing (ECAM) to form the single continuous member. The heatsink 306 and the bottom cover 504 of the heat transfer device 302 can be formed from the same material.

Furthermore, the wicked structure layer 506 forms a part of the single continuous member (or body). The wicked structure layer 506 is integrated with the heat transfer device 302 to form the single continuous member. In other words, the heat transfer device 302 and the wicked structure layer 506 are a single continuous member that is uninterrupted in space; the heat transfer device 302 and the wicked structure layer 506 are a single continuous member that is unbroken. Specifically, the wicked structure layer 506 can be integrated with the heat transfer device 302 through ECAM to form the single continuous member. That is, the single continuous member can include the bottom cover 504, the heatsink 306, and the wicked structure layer 506 form the single continuous member. In other words, the bottom cover 504 of the heat transfer device 302, the heatsink 306, and the wicked structure layer 506 are a single continuous member that is uninterrupted in space; the bottom cover 504 of the heat transfer device 302, the heatsink 306, and the wicked structure 506 are a single continuous member that is unbroken. The heatsink 306, the bottom cover 504 of the heat transfer device 302, and the wicked structure layer 506 can be formed from the same material.

The bottom cover 504 is coupled with the top cover 502. In some examples, the bottom cover 504 is brazed with the top cover 502. To that end, as the bottom cover 504 is a part of the single continuous member, the single continuous member (including the bottom cover 504, the heatsink 306, and the wicked structure layer 506) is coupled with the top cover 502.

In some examples, when the heatsink 306 is a honeycomb heatsink (as shown in FIG. 7), the honeycomb unit size can be adjusted to increase cooling efficiency of the thermal apparatus 210 by optimizing surface area for airflow.

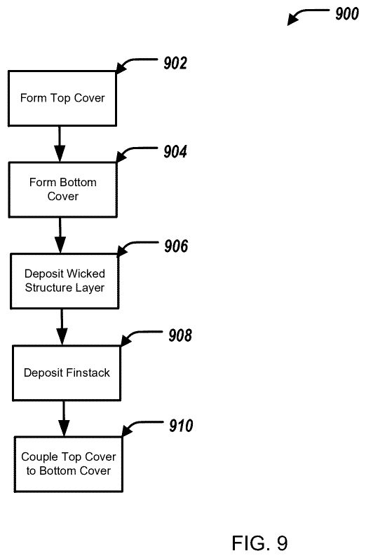

FIG. 9 illustrates a flowchart depicting selected elements of an embodiment of a method 900 for forming the thermal apparatus 210, with reference to FIGS. 1-8. It is noted that certain operations described in method 900 may be optional or may be rearranged in different embodiments.

The top cover 502 of the heat transfer device 302 is formed, at 902. The bottom cover 504 of the heat transfer device 302 is formed, at 904. The wicked structure layer 506 is deposited on the first surface 520 of the bottom cover 504 of the heat transfer device 302, at 906. In some examples, the wicked structure layer 506 is deposited on the first surface 520 of the bottom cover 504 of the heat transfer device 302 by ECAM. The heatsink 306 is deposited on the second surface 522 of the bottom cover 504 of the heat transfer device 302, at 908. In some examples, the heatsink 306 is deposited on the second surface 522 of the bottom cover 504 of the heat transfer device 302 by ECAM. The bottom cover 504, the wicked structure layer 506, and the heatsink 306 form a single continuous member (or body). The top cover 502 is coupled to the bottom cover 504 to form the heat transfer device 302, at 910. That is, the single continuous member that includes the bottom cover 504, the wicked structure layer 506, and the heatsink 306 is coupled to the top cover 502 to form the heat transfer device 302.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. A thermal apparatus for an information handling system, comprising:
a heat transfer device, including:
a top cover;
a bottom cover opposite to the top cover, the bottom cover including a first surface and a second surface opposite to the first surface; and
a wicked structure layer positioned on the first surface of the bottom cover;
a heatsink formed on the heat transfer device; and
a fan coupled to the heat transfer device and the fin stack,
wherein the bottom cover and the heatsink are a single continuous member.

2. The thermal apparatus of claim 1, wherein the single continuous member further includes the wicked structure layer.

3. The thermal apparatus of claim 2, wherein the bottom cover, the heatsink, and the wicked structure layer are formed from the same material.

4. The thermal apparatus of claim 3, wherein the heatsink is formed on the second surface of the bottom cover.

5. The thermal apparatus of claim 1, wherein the heatsink is a parallel finstack.

6. The thermal apparatus of claim 1, wherein the heatsink is a honeycomb heatsink.

7. The thermal apparatus of claim 1, wherein the single continuous member is coupled to the top cover.

8. The thermal apparatus of claim 1, wherein the heat transfer device is a vapor chamber.

9. The thermal apparatus of claim 1, wherein the heat transfer device is a heat pipe.

10. A method of forming a thermal apparatus, including:
forming a top cover of a heat transfer device;
forming a bottom cover of the heat transfer device;
depositing a wicked structure layer on a first surface of the bottom cover of the heat transfer device;
depositing a heatsink on a second surface of the bottom cover of the heat transfer device, the second surface opposite the first surface of the heat transfer device, wherein the wicked structure layer, the bottom cover, and the heatsink are a single continuous member; and
coupling the top cover to the bottom cover to form the heat transfer device.

11. The method of claim 10, wherein the wicked structure layer is deposited on the first surface of the bottom cover of the heat transfer device by electrochemical additive manufacturing (ECAM).

12. The method of claim 10, wherein the heatsink is deposited on the first surface of the bottom cover of the heat transfer device by electrochemical additive manufacturing (ECAM).

13. The method of claim 10, wherein the bottom cover, the heatsink, and the wicked structure layer are formed from the same material.

14. An information handling system, comprising:
a processor;
memory media storing instructions executable by the processor to perform operations;
a thermal apparatus to dissipate heat generated by the processor, including:
a heat transfer device, including:
a top cover;
a bottom cover opposite to the top cover, the bottom cover including a first surface and a second surface opposite to the first surface; and
a wicked structure layer positioned on the first surface of the bottom cover;
a heatsink formed on the heat transfer device; and
a fan coupled to the heat transfer device and the fin stack,
wherein the bottom cover and the heatsink are a single continuous member.

15. The information handling system of claim 14, wherein the single continuous member further includes the wicked structure layer.

16. The information handling system of claim 15, wherein the bottom cover, the heatsink, and the wicked structure layer are formed from the same material.

17. The information handling system of claim 16, wherein the heatsink is formed on the second surface of the bottom cover.

18. The information handling system of claim 14, wherein the heatsink is a parallel finstack.

19. The information handling system of claim 14, wherein the heatsink is a honeycomb heatsink.

20. The information handling system of claim 14, wherein the single continuous member is coupled to the top cover.
